(19) United States
(12) Patent Application Publication
(10) Pub. No.: US 2013/0200937 A1
(43) Pub. Date: Aug. 8, 2013

(54) DELAY LINE WITH CELL BY CELL POWER DOWN CAPABILITY

(71) Applicants: Vishwanath A. PATIL, South Burlington, VT (US); Pradeep THIAGARAJAN, South Burlington, VT (US)

(72) Inventors: Vishwanath A. PATIL, South Burlington, VT (US); Pradeep THIAGARAJAN, South Burlington, VT (US)

(73) Assignee: INTERNATIONAL BUSINESS MACHINES CORPORATION, Armonk, NY (US)

(21) Appl. No.: 13/367,613

(22) Filed: Feb. 7, 2012

(51) Int. Cl. H03H 11/26

(52) U.S. Cl. 327/284; 327/288

(57) ABSTRACT

A delay line with cell by cell power down capability and methods of use are provided. The delay cell includes a first gate transistor coupled to a voltage supply, a second gate transistor coupled to ground, and a reset signal provided to at least one of the first gate transistor and the second gate transistor. The reset signal turns the delay cell on and off.

### FIELD OF THE INVENTION

The invention relates to semiconductor structures and, more particularly, to a delay line with cell by cell power down capability and methods of use.

### BACKGROUND

Delay lines are used to precisely delay an incoming signal, such as a strobe or clock, by a value that is a function of a master clock period. These master clocks can be generated by a phase-locked loop (PLL) with a ring voltage controlled oscillator (VCO) or a delay-locked loop (DLL), provided that delay elements used in the PLL with the ring VCO or the DLL mimic the delay elements used in the delay line. The delay of the delay elements can be controlled by a control signal(s). The same control signal used in the PLL or DLL can also be used to control the delay line elements. When the PLL or DLL locks to a desired frequency, a corresponding control signal configures the delay elements in the delay line as a function of that frequency.

The delay elements are inverter-based circuits which provide pulse delay control. More specifically, the delay elements include a gate inverter having a first inverter and a second inverter, where each inverter has a pull-up pFET transistor and an nFET pull-down transistor. A method for controlling delay elements is a current starved approach where control signals control the current through the inverter. More specifically, the control signal is provided to one or more tail transistors which control the current through the inverters. However, the same control signal is provided to each delay element. As a result, the delay elements of the delay line cannot be individually operated. That is, either all of the delay elements are operational or all of the delay elements are disabled. As a result, the delay line may be operating with unnecessary delay elements, i.e., delay elements not required for a specific application or mode of operation of that delay line. Consequently, having unnecessary delay elements operational increases real time operational power.

Accordingly, there exists a need in the art to overcome the deficiencies and limitations described hereinabove.

### SUMMARY

In an aspect of the invention, a delay cell uses one or more analog control voltages and comprises a first gate transistor coupled to a voltage supply, a second gate transistor coupled to ground, and a reset signal provided to at least one of the first gate transistor and the second gate transistor. The reset signal turns the delay cell on and off.

In an aspect of the invention, a delay line circuit comprises a plurality of delay cells connected in series and a reset signal provided to the plurality of delay cells. The reset signal turns the delay cells on and off individually, and is a binary code provided by a decoder. The reset signal having a high logic turns the delay cell off and the reset signal having a low logic turns the delay cell on.

In an aspect of the invention, a method comprises providing a reset signal to a plurality of delay cells of a delay line circuit. The method also comprises turning at least one of the plurality of delay cells off, cell by cell, based on the reset signal.

In another aspect of the invention, a design structure tangibly embodied in a machine readable storage medium for designing, manufacturing, or testing an integrated circuit is provided. The design structure comprises the structures of the present invention. In further embodiments, a hardware description language (HDL) design structure encoded on a machine-readable data storage medium comprises elements that when processed in a computer-aided design system generates a machine-executable representation of the delay line with cell by cell power down capability, which comprises the structures of the present invention. In still further embodiments, a method in a computer-aided design system is provided for generating a functional design model of the delay line with cell by cell power down capability. The method comprises generating a functional representation of the structural elements of the delay line with cell by cell power down capability.

### BRIEF DESCRIPTION OF THE SEVERAL VIEWS OF THE DRAWINGS

The present invention is further described in the detailed description which follows, in reference to the noted plurality of drawings by way of non-limiting examples of exemplary embodiments of the present invention, in which like reference numerals represent similar parts throughout the several views of the drawings, and wherein:

FIG. 1 shows a block diagram of a phase-locked loop in accordance with aspects of the present invention;

FIG. 2 shows a block diagram of a delay-locked loop in accordance with aspects of the present invention;

FIG. 3 shows a delay cell having a single input and a single output in accordance with aspects of the present invention;

FIG. 4 shows an alternate delay cell having a single input and a single output in accordance with aspects of the present invention;

FIG. 5 shows a delay cell having a dual input and a dual output in accordance with aspects of the present invention;

FIG. 6 shows an alternate delay cell having a dual input and a dual output in accordance with aspects of the present invention;

FIG. 7 shows a block diagram of a binary decoder in accordance with aspects of the present invention;

FIG. 8 shows a high level schematic diagram of a delay line circuit in accordance with aspects of the present invention;

FIG. 9 shows a delay line circuit having a single input and a single output in accordance with aspects of the present invention;

FIG. 10 shows an alternate delay line circuit having a dual input and a dual output in accordance with aspects of the present invention;

FIGS. 11 and 12 show performance graphs of a delay line circuit in accordance with aspects of the present invention; and

FIG. 13 is a flow diagram of a design process used in semiconductor design, manufacture, and/or test.

### DETAILED DESCRIPTION

The invention relates to semiconductor structures and, more particularly, to a delay line with cell by cell power down capability and methods of use. In embodiments, the delay line includes an input signal, such as a clock or a strobe, and one or more control voltages provided to one or more delay cells. In addition, a reset signal is provided to each delay cell, which is used to power the delay cell off and on. An output of the delay line circuit is provided to a circuit, such as, for example, a phase-locked loop, a delay-locked loop, a phase rotator, etc.

According to aspects of the invention, the delay cell includes a first gate transistor and a second gate transistor. In embodiments, a gate of the first gate transistor is coupled to a reset signal and a gate of the second gate transistor is coupled to an inverted reset signal. In embodiments, the gate of the first gate transistor is coupled to an inverted reset signal and the gate of the second gate transistor is coupled to a reset signal. The delay cell also includes a first tail transistor and a second tail transistor coupled to the first gate transistor and second gate transistor, respectively. In embodiments, gates of the tail transistors are coupled to a control voltage. In alternate embodiments, gates of the tail transistors are selectively coupled to the control voltages. The delay cell uses one or more analog control voltages (e.g., control signals) to control at least one of the first and second tail transistors. In this way, the delay cell is analog in nature due to current regulation created in the tail transistors by the analog value of the control voltages.

In embodiments, the delay cell also includes a body inverter, i.e., a buffer, having a single input and a single output. The body inverter includes two inverters, each inverter having a pull-up pFET transistor and a pull-down nFET transistor. In embodiments, the delay cell includes a double inverter having a dual input and a dual output. The dual inverter includes two inverters, each inverter having a pull-up pFET transistor, a pull-down nFET transistor, an input, and an output.

Advantageously, the present invention provides for a programmable delay line circuit having one or more delay cells which can be disabled by a reset signal. Accordingly, the present invention provides for a calibration mechanism to disable delay cells when an application requires a specific number of operational delay cells. That is, for each application, a user can determine the number of delay cells necessary for a functional mode or power down mode, and disable unnecessary delay cells. In embodiments, when a delay cell is disabled, a clock propagation to succeeding cells is also cut off.

Accordingly, the present invention advantageously provides for reduced power consumption. More specifically, by disabling one or more delay cells, power savings can be in the order of uAs (microamps) to mAs (milliamps), depending on current consumption per delay cell, the number of delay cells per delay line circuit, a frequency of operation, and process, voltage and temperature (PVT) corners. For example, the power savings can be up to 200 uA per delay cell per delay line circuit while operating at about 1066 Mhz. In embodiments, the present invention may also be utilized in many technologies including, but not limited to, 45 nm, 32 nm, and 22 nm technologies.

Additionally, an output of a disabled delay cell can be configured to a specific value, thus avoiding floating values which cause unwanted current sneak paths in subsequent delay cells along the delay line circuit.

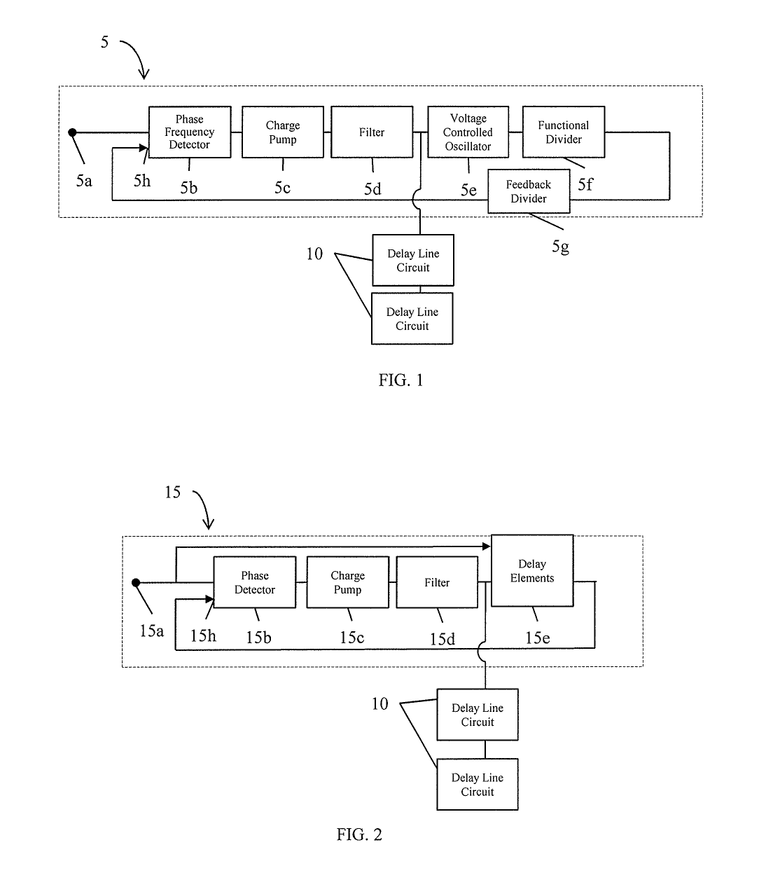

FIG. 1 shows a block diagram of a phase locked loop (PLL) and an associated delay line circuit in accordance with aspects of the invention. More specifically, the PLL 5 includes an input signal 5a having a reference frequency connected to a phase frequency detector 5b. The phase frequency detector 5b generates one or more signals which represents the difference in phase between two inputs, e.g., the input signal 5a and an output from a feedback divider 5g, e.g., feedback signal 5h. In embodiments, the phase frequency detector 5b is analog-based, such that the phase frequency detector 5b generates a unique voltage for a phase difference. One or more outputs of the phase frequency detector 5b is connected to a charge pump 5c, and the charge pump 5c is further connected to a filter 5d. An output of the filter 5d is connected to a VCO 5e and to one or more delay line circuits 10 (which may also be referred to as a delay line 10). The VCO 5e includes a closed loop ring of delay elements whose delay varies in response to one or more control voltages, and the frequency of the VCO 5e at any given time may be the inverse of a sum of the delay of all the delay elements in the closed loop ring. In embodiments, the delay elements of the VCO 5e are identical to delay cells used in the delay line circuits 10 to achieve delay matching; although non-identical cells may also be used within the scope of the invention. In embodiments, the output of the VCO 5e is connected to a functional divider 5f, and an output of the function divider 5f is coupled to the feedback divider 5g. The feedback signal 5h is provided to the phase frequency detector 5b. When the PLL 5 locks to a desired frequency, the delay of each delay element in the VCO 5e is configured by a corresponding control signal, such that a delay of the delay element equals an inverse of a product of the frequency and a total number of delay elements in the ring. Additionally, the one or more corresponding control voltages configure delay cells in the delay line circuit 10 as a function of that frequency, and the delay cells have a same delay as the delay elements in the VCO 5e.

FIG. 2 shows a block diagram of a delay locked loop (DLL) and an associated delay line circuit in accordance with aspects of the invention. More specifically, the DLL 15 includes an input signal 15a having a reference frequency connected to a phase detector 15b and delay elements 15e. The phase detector 15b generates a signal which represents the difference in phase between two signal inputs, one being the input signal 15a and the second input being an output 15h of delay elements 15e. One or more outputs of the phase detector 15b is connected to a charge pump 15c. An output of the charge pump 15c is provided to a filter 15d, and an output of the filter 15d is provided to the delay elements 15e and one or more delay line circuits 10. In embodiments, the delay elements 15e include a series of delay cells in a non-loop fashion. In embodiments, the delay elements 15e are identical to delay cells used in the delay line circuits 10 to achieve delay matching; although non-identical cells may also be used within the scope of the invention. The output 15h of the delay elements 15e is provided to the phase detector 15b, as feedback. When the DLL 15 locks to a desired phase, the delay elements 15e, e.g., the delay cells, are configured by one or more corresponding control voltages, such that the delay of the delay cell equals an N^{th} fraction of a time period of the input signal 15a, where N is the number of delay cells in delay element 15e. Additionally, the one or more corresponding control voltages configure the delay cells in delay line circuit 10 as a function of that delay.

FIG. 3 shows a delay cell implemented in the delay line circuit 10 (of FIGS. 1 and 2) according to aspects of the invention. More specifically, the delay cell 20 includes a first gate transistor 22. A source of the first gate transistor 22 is connected to a voltage supply VPWR and a gate of the first gate transistor 22 is connected to a reset signal RST. A drain of the first gate transistor 22 is connected to a source of a first tail transistor 24. In embodiments, a gate of the first tail transistor 24 is coupled to a first control voltage 62a. In embodiments, the first gate transistor 22 and the first tail transistor 24 are pFET transistors.

As shown in FIG. 3, the delay cell 20 further includes a body inverter 30. In embodiments, the body inverter 30 includes a first inverter 32 and a second inverter 34. In embodiments, the first inverter 32 includes a first pull-up pFET transistor 32a and a first pull-down nFET transistor 32b, and the second inverter 34 includes a second pull-up pFET transistor 34a and a second pull-down nFET transistor 34b. A source of the first pFET transistor 32a is connected to a drain of the first tail transistor 24 and a source of the second pFET transistor 34a is connected to the drain of the first gate transistor 22. A drain of the first nFET transistor 32b is connected to a drain of the first pFET transistor 32a, and a source of the first nFET transistor 32b is connected to a drain of a second tail transistor 28. Additionally, a drain of the second nFET transistor 34b is connected to a drain of the second pFET transistor 34a, and a source of the second nFET transistor 34b is connected to a drain of a second gate transistor 26. Gates of the first pFET transistor 32a and first nFET transistor 32b are coupled to an input signal A, e.g., a clock or a strobe. Gates of the second pFET transistor 34a and the second nFET transistor 34b are coupled to the drains of the first pFET transistor 32a and first nFET transistor 32b, i.e, an output of the first inverter 32. The drains of the second pFET transistor 34a and the second nFET transistor 34b are the output Z of the body inverter 30. In this way, the delay cell 20 has a true in, true out (TITO) configuration. In embodiments, the output Z of a disabled delay cell 20 can be configured to a specific value (i.e., low or high) to avoid floating values which cause unwanted current sneak paths in a subsequent delay cell(s).

Still referring to FIG. 3, a source of the second gate transistor 26 is connected to ground GND. A reset signal RST is provided to an inverter 21 and an output RSTB of the inverter 21 is coupled to a gate of the second gate transistor 26. A drain of the second gate transistor 26 is connected to a source of the second tail transistor 28. In embodiments, a gate of the second tail transistor 28 is coupled to a second control voltage 62b. In embodiments, the second gate transistor 26 and the second tail transistor 28 are nFET transistors. In embodiments, the delay cell 20 may be operated with a single tail transistor, e.g., the first tail transistor 24 or the second tail transistor 28, and as such, a single control voltage is be utilized.

In alternate embodiments, instead of an output of the first inverter 32 provided to the second inverter 34, the reverse can be performed. More specifically, an output of the second inverter 34 can be provided as an input to the gates of the transistors of the first inverter 32, and as such, the drains of the inverters of the first inverter 32 are the output Z in the second inverter 34. In either case, the first inverter 32 functions as a current controlled inverter, and the second inverter 34 creates an inversion effect to act as a buffer delay cell. In further embodiments, the delay cell 20 can be implemented only using the first inverter 32 without utilizing the second inverter 34. In this way, the delay cell 20 functions as an inverter delay cell.

In embodiments, the first and second control voltages 62a, 62b are matched (e.g., equal to one another) to maintain an equal fall time and an equal rise time of the output Z. In alternate embodiments, the first and second control voltages 62a, 62b are unique (e.g., different from one another), such that the first control voltage 62a controls a current through the first tail transistor 24 to create the required rising delay of the output the first inverter 32 through the first pull-up transistor 32a, and the second control voltage 62b controls a current through the second tail transistor 28 to create the required falling delay of the output of the first inverter 32 through the first pull-down transistor 32b. In embodiments, when the delay cell 20 having two tail transistors 24, 28 is implemented in a VCO (e.g., VCO 5e of FIG. 1), the control voltages 62a, 62b are unique. Accordingly, the output of a filter (e.g., filter 5d of FIG. 1) can be processed to form the control voltages 62a, 62b. Alternatively, two outputs of a differential charge pump (e.g., charge pump 5c of FIG. 1), can be provided to two filters 5d or a differential filter. In embodiments, when the VCO 5e is implemented with a single tail transistor, the filter 5d has a single output.

In embodiments, the first gate transistor 22 and the second gate transistor 26 are used to turn the delay cell 20 on and off. In embodiments, for example, when the reset signal RST is high (i.e., RST=1) and the inverted reset signal RSTB is low (i.e., RSTB=0), the first gate transistor 22 and second gate transistor 26 are turned off, such that the first gate transistor 22 decouples the first tail transistor 24 from the voltage supply VPWR and the second gate transistor 26 decouples the second tail transistor 28 from ground GND. As should be understood by those of ordinary skill in the art a high logic, i.e., RST=1, turns a pFET transistor off, and a low logic, i.e., RSTB=0, turns an nFET transistor off. As a result, the delay cell 20 is disabled when both the first gate transistor 22 and the second gate transistor 26 are off. In this way, there is no current path to the voltage supply VPWR and ground GND for the first and second tail transistors 24, 28, respectively, to regulate a current through their respective gate voltages, and there is no clock switching activity in the delay cell 20.

In embodiments, when the reset signal RST is low (i.e., RST=0) and the inverted reset signal RSTB is high (i.e., RSTB=1), the first gate transistor 22 and the second gate transistor 26 are turned on, such that the first tail transistor 24 is coupled to the voltage supply VPWR and the second tail transistor 28 is coupled to ground GND. As should be understood by those of ordinary skill in the art, a low logic, i.e., RST=0, turns a pFET transistor on, and a high logic, i.e., RSTB=1, turns an nFET transistor on. As a result, the delay cell 20 is turned on when both the first gate transistor 22 and the second gate transistor 26 are turned on. In this way, current paths are provided to the voltage supply VPWR and ground GND for the first and second tail transistors 24, 28, respectively, to regulate the current based on their respective gate voltages, and the delay of the delay cell 20 can be configured. That is, when the reset signal is low, the delay cell 20 is turned on, and when the reset signal is high, the delay cell 20 is disabled.

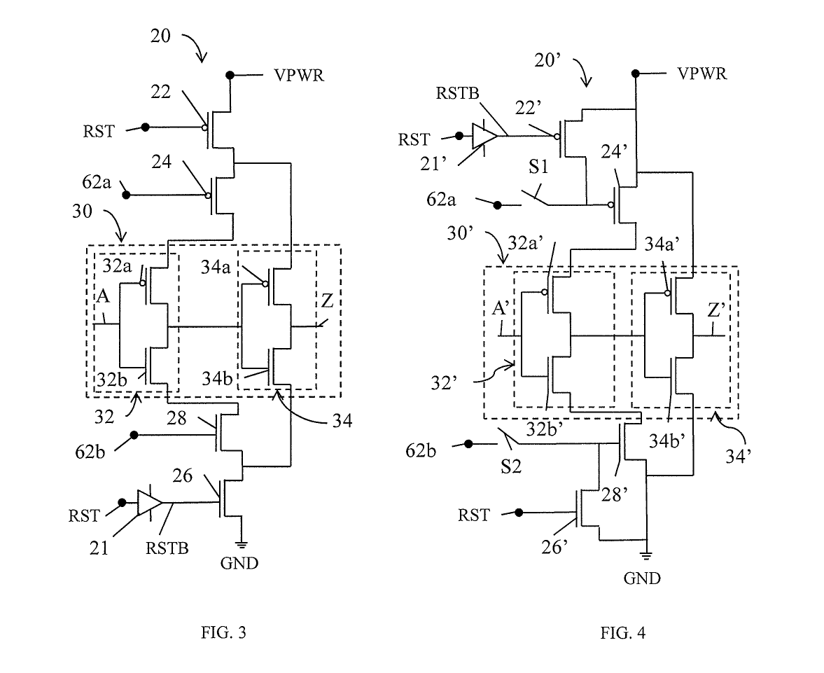

FIG. 4 shows an alternate delay cell 20′ according to aspects of the invention. In particular, FIG. 4 shows a reset signal RST provided to an inverter 21′. An output RSTB of the inverter 21′ is provided to a gate of a first gate transistor 22′. Additionally, FIG. 4 shows gates of a first tail transistor 24′ and a second tail transistor 28′ selectively coupled to the first control voltage 62a and the second control voltage 62b, respectively, by a first switch S1 and a second switch S2, respectively. In addition, the gate of the first tail transistor 24′ is coupled to a drain of the first gate transistor 22′, and the gate of the second tail transistor 28′ is coupled to a drain of the second gate transistor 26′. A source of the first tail transistor 24′ is coupled to a voltage supply VPWR and a source of the second tail transistor 28′ is connected to ground GND.

As further shown in FIG. 4, the delay cell 20′ further includes a body inverter 30′. In embodiments, the body inverter 30′ includes a first inverter 32′ and a second inverter 34′. In embodiments, the first inverter 32′ includes a first pull-up pFET transistor 32a′ and a first pull-down nFET transistor 32b′, and the second inverter 34′ includes a second pull-up pFET transistor 34a′ and a second pull-down nFET transistor 34b′. A source of the first pFET transistor 32a′ is connected to a drain of the first tail transistor 24′ and a source of the second pFET transistor 34a′ is connected to the voltage supply VPWR. A drain of the first nFET transistor 32b′ is connected to a drain of the first pFET transistor 32a′ and a source of the first nFET transistor 32b′ is connected to a drain of a second tail transistor 28′. Similarly, a drain of the second nFET transistor 34b′ is connected to a drain of the second pFET transistor 34a′ and a source of the second nFET transistor 34b′ is connected to ground GND. Gates of the first pFET transistor 32a′ and first nFET transistor 32b′ are coupled to an input signal A′, e.g., a clock or a strobe. Gates of the second pFET transistor 34a′ and the second nFET transistor 34b′ are coupled to the drains of the first pFET transistor 32a′ and first nFET transistor 32b′. The drains of the second pFET transistor 34a′ and the second nFET 34b′ transistor are the output Z′ of the body inverter 30′. In this way, the delay cell 20′ has a true in, true out (TITO) configuration. In embodiments, the output Z′ of a disabled delay cell 20′ can be configured to a specific value (i.e., low or high) to avoid floating values which cause unwanted current sneak paths in a subsequent delay cell(s).

In embodiments, when the reset signal RST is high (i.e., RST=1), the switches S1, S2 are open. Additionally, the output RSTB of the inverter 21′ is low (i.e., RSTB=0). In this way, when the reset signal RST is high, the first and second gate transistors 22′, 26′ are turned on and the first and second tail transistors 24′ and 28′ are turned off. As a result, the first inverter 32′ is decoupled from the voltage supply VPWR and ground GND, and thus, the delay cell 20′ is off when RST=1. In this way, there is no current path to the voltage supply VPWR and ground GND for the first and second tail transistors 24′, 28′, respectively, to regulate the current through their respective gate voltages, and there is no clock switching activity in the delay cell 20′.

In embodiments, when the reset signal RST is low (i.e., RST=0), the switches S1, S2 are closed and the output RSTB of the inverter 21′ is high. In this way, when the reset signal RST is low, the first gate transistor 22′ and the second gate transistor 26′ are turned off, and the gates of the first tail transistor 24′ and the second tail transistor 28′ are coupled to a first control voltage 62a and a second control voltage 62b, respectively. As a result, the body inverter 30′ is coupled to the voltage supply VPWR and ground GND, and thus, the delay cell 20′ is turned on when RST=0. In this way, current paths are provided to the voltage supply VPWR and ground GND for the first and second tail transistors 24′, 28′, respectively, to regulate the current based on their respective gate voltages, and the delay of the delay cell 20′ can be configured. As such, when the reset signal is low, the delay cell 20′ is turned on, and when the reset signal is high, the delay cell 20′ is disabled.

In alternate embodiments, instead of an output of the first inverter 32′ provided to the second inverter 34′, the reverse can be performed, as described herein. In either case, the first inverter 32′ functions as a current controlled inverter, and the second inverter 34′ creates an inversion effect to act as a buffer delay cell. In further embodiments, the delay cell 20′ can be implemented only using the first inverter 32′ without utilizing the second inverter 34′. In this way, the delay cell 20′ functions as an inverter delay cell. In embodiments, the first and second control voltages 62a, 62b are matched to maintain an equal fall time and an equal rise time of the output Z′. In alternate embodiments, the first and second control voltages 62a, 62b are unique. In embodiments, when the delay cell 20′ having two tail transistors 24′, 28′ is implemented in a VCO (e.g., VCO 5e of FIG. 1), the control voltages 62a, 62b are unique. In embodiments, when the VCO is implemented with a single tail transistor, a filter (e.g., filter 5d of FIG. 1) has a single output.

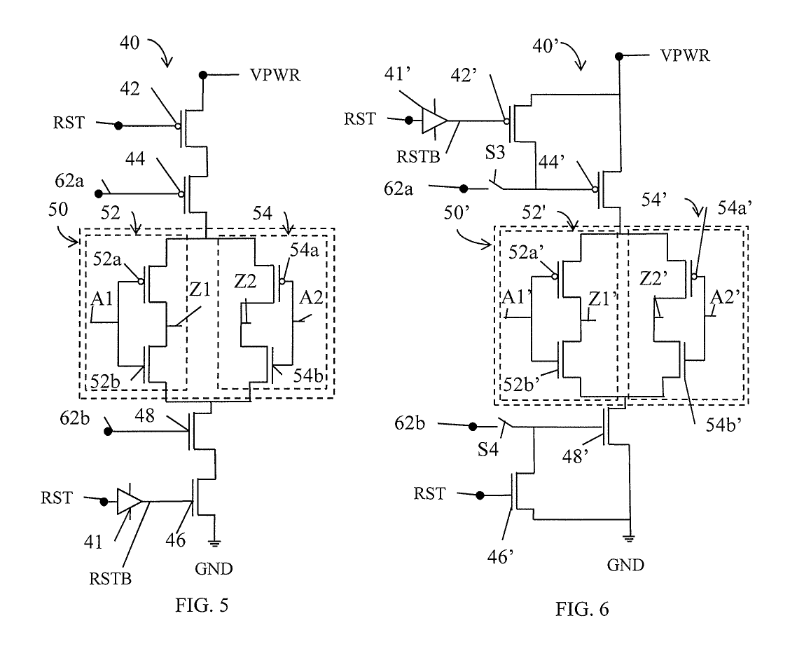

FIG. 5 shows a delay cell 40 having a dual input and dual output. More specifically, in comparison to FIG. 3, the delay cell 40 includes a body inverter 50. In embodiments, the body inverter 50 is a double inverter having a first inverter 52 and a second inverter 54, each inverter 52, 54 having an input A1, A2, respectively, and an output Z1, Z2, respectively. In embodiments, the first inverter 52 includes a first pull-up pFET transistor 52a and a first pull-down nFET transistor 52b, and the second inverter 54 includes a second pull-up pFET transistor 54a and a second pull-down nFET transistor 54b. In embodiments, gates of the first pFET transistor 52a and the first nFET transistor 52b are coupled to the input A1, and gates of the second pFET transistor 54a and the second down nFET transistor 54b are coupled to the input A2. In embodiments, a drain of the first pFET transistor 52a is coupled to a drain of the first nFET transistor 52b. The drains of the first pFET transistor 52a and the first nFET transistor 52b are the output Z1. Similarly, a drain of the second pFET transistor 54a is coupled to a drain of the second nFET transistor 54b. The drains of the second pFET transistor 54a and the second nFET transistor 54b are the output Z2. That is, the delay cell 40 has a dual in, dual out (DIDO) configuration. In addition, in comparison to FIG. 3, sources of the first pFET transistor 52a and second pFET transistor 54a are coupled to a drain of a first tail transistor 44, and sources of the first nFET transistor 52b and second nFET transistor 54b are coupled to a drain of a second tail transistor 46. The remaining structure of FIG. 5 is the same as the structure shown in FIG. 3.

More specifically, as shown in FIG. 5, the delay cell 40 includes a first gate transistor 42. In embodiments, a source of the first gate transistor 42 is connected to a voltage supply VPWR and a gate of the first gate transistor 42 is connected to a reset signal RST. A drain of the first gate transistor 42 is connected to a source of the first tail transistor 44. In embodiments, a gate of the first tail transistor 44 is coupled to a first control voltage 62a. In embodiments, the first gate transistor 42 and the first tail transistor 44 are pFET transistors. A reset signal RST is provided to an inverter 41 and an output RSTB of the inverter 41 is provided to a gate of a second gate transistor 46. A source of the second gate transistor 46 is connected to ground GND and a drain of the second gate transistor 46 is connected to a source of the second tail transistor 48. In embodiments, a gate of the second tail transistor 48 is coupled to a second control voltage 62b. In embodiments, the second gate transistor 46 and the second tail transistor 48 are nFET transistors. In embodiments, the delay cell 40 may be operated with a single tail transistor, e.g., the first tail transistor 44 or the second tail transistor 48, and as such, a single control voltage is be utilized. In embodiments, the outputs Z1 and Z2 of a disabled delay cell 40 can be configured to a specific value (i.e., low or high) to avoid floating values which cause unwanted current sneak paths in the subsequent delay cell(s).

In embodiments, the first and second control voltages 62a, 62b are matched to maintain equal fall time and rise time of the outputs Z1, Z2. In alternate embodiments, the first and second control voltages 62a, 62b are unique. In embodiments, when the delay cell 40 having two tail transistors 44, 48 is implemented in a VCO (e.g., VCO 5e of FIG. 1), the control voltages 62a, 62b are unique. In embodiments, when the VCO is implemented with a single tail transistor, the filter (e.g., filter 5d of FIG. 1) has a single output. Also, in further embodiments, locations of the first gate transistor 42 with the reset signal RST coupled to its gate and the first tail transistor 44 with the control voltage 62a coupled to its gate can be reversed, such that the first tail transistor 44 is coupled to the voltage supply VPWR, and the delay cell 40 achieves the same functionality. In a similar fashion, the location of the second gate transistor 46 and second tail transistor 48 can also be reversed, such that the second tail transistor 48 is coupled to ground GND, and the delay cell 40 achieves the same functionality.

In embodiments, the first gate transistor 42 and the second gate transistor 46 are used to turn the delay cell 40 on and off. In embodiments, for example, when the reset signal RST is high (i.e., RST=1), the first gate transistor 42 and second gate transistor 46 are turned off, such that the first gate transistor 42 decouples the first tail transistor 44 from the voltage supply VPWR and the second gate transistor 46 decouples the second tail transistor 48 from ground GND. As a result, the delay cell 40 is disabled when both the first gate transistor 42 and the second gate transistor 46 are off. In this way, there is no current path to the voltage supply VPWR and ground GND for the first and second tail transistors 44, 48, respectively, to regulate the current through their respective gate voltages, and there is no clock switching activity in the delay cell 40.

In embodiments, when the reset signal RST is low (i.e., RST=0), the first gate transistor 42 and the second gate transistor 46 are turned on, such that the first tail transistor 44 is coupled to the voltage supply VPWR and the second tail transistor 48 is coupled to ground GND. As a result, the delay cell 40 is turned on when both the first gate transistor 42 and the second gate transistor 46 are turned on. In this way, current paths are provided to the voltage supply VPWR and ground GND for the first and second tail transistors 44, 48, respectively, to regulate the current based on their respective gate voltages, and the delay of the delay cell 40 can be configured. In this way, when the reset signal is low, the delay cell 40 is turned on, and when the reset signal is high, the delay cell 40 is disabled.

FIG. 6 shows an alternate delay cell 40′ having a dual input and a dual output. More specifically, in comparison to FIG. 4, the delay cell 40′ includes a body inverter 50′. In embodiments, the body inverter 50′ is a double inverter having a first inverter 52′ and a second inverter 54′, each inverter 52′, 54′ having an input A1′, A2′, respectively, and an output Z1′, Z2′, respectively. In embodiments, gates of the first pFET transistor 52a′ and the first nFET transistor 52b′ are coupled to the input A1′, and gates of the second pFET transistor 54a′ and the second down nFET transistor 54b′ are coupled to the input A2′. In embodiments, a drain of the first pFET transistor 52a′ is coupled to a drain of the first nFET transistor 52b′. The drains of the first pFET transistor 52a′ and the first nFET transistor 52b′ are the output Z1′. Similarly, a drain of the second pFET transistor 54a′ is coupled to a drain of the second nFET transistor 54b′. The drains of the second pFET transistor 54a′ and the second nFET transistor 54b′ are the output Z2. That is, the delay cell 40′ has a dual in, dual out (DIDO) configuration. In addition, in comparison to FIG. 4, sources of the first pFET transistor 52a′ and second pFET transistor 54a′ are coupled to a drain of a first tail transistor 44′, and sources of the first nFET transistor 52b′ and second nFET transistor 54b′ are coupled to a drain of a second tail transistor 48′. The remaining structure of FIG. 6 is the same as the structure shown in FIG. 4.

More specifically, as shown in FIG. 6, a reset signal RST is provided to an inverter 41′ and an output RSTB of the inverter 41′ provided to a gate of a first gate transistor 42′. Additionally, FIG. 6 shows the first tail transistor 44′ and the second tail transistor 48′ each selectively coupled to the first control voltage 62a and the second control voltage 62b, respectively, by a first switch S3 and a second switch S4, respectively. In addition, the gate of the first tail transistor 44′ is coupled to a drain of the first gate transistor 42′ and the gate of the second tail transistor 48′ is coupled to a drain of the second gate transistor 46′. A source of the first tail transistor 44′ is coupled to a voltage supply VPWR and a source of the second tail transistor 48′ is connected to ground GND. In embodiments, the outputs Z1′ and Z2′ of a disabled delay cell 40′ can be configured to a specific value (i.e., low or high) to avoid floating values which cause unwanted current sneak paths in the subsequent delay cell(s).

In embodiments, when the reset signal RST is high (i.e., RST=1), the switches S3, S4 are open. Additionally, the output RSTB of the inverter 41′ is low (i.e., RSTB=0). In this way, when the reset signal RST is high, the first and second gate transistors 42′, 46′ are turned on and the first and second tail transistors 44′ and 48′ are turned off. As a result, the inverters 52′ and 54′ are decoupled from the voltage supply VPWR and ground GND, and thus, the delay cell 40′ is off when RST=1. In this way, there is no current path to the voltage supply VPWR and ground GND for the first and second tail transistors 44′, 48′, respectively, to regulate the current through their respective gate voltages, and there is no clock switching activity in the delay cell 40′.

In embodiments, when the reset signal RST is low (i.e., RST=0), the switches S3, S4 are closed and the output RSTB of the inverter 41′ is high. In this way, when the reset signal RST is low, the first gate transistor 42′ and the second gate transistor 46′ are turned off, and the first tail transistor 44′ and the second tail transistor 48′ are turned on. In this way, current paths are provided to the voltage supply VPWR and ground GND for the first and second tail transistors 44′, 48′, respectively, to regulate the current based on their respective gate voltages, and the delay of the delay cell 40′ can be configured. As a result, the first inverters 52′, 54′ are coupled to the voltage supply VPWR and ground GND, and thus, the delay cell 40′ is turned on when RST=0. As such, when the reset signal is low, the delay cell 40′ is turned on, and when the reset signal is high, the delay cell 40′ is disabled.

In embodiments, the first and second control voltages 62a, 62b are matched to maintain equal fall time and rise time of the outputs Z1′, Z2′. In alternate embodiments, the first and second control voltages 62a, 62b are unique. In embodiments, when the delay cell 40′ having two tail transistors 44′, 48′ is implemented in a VCO (e.g., VCO 5e of FIG. 1), the control voltages 62a, 62b are unique. In embodiments, when the VCO is implemented with a single tail transistor, the filter (e.g., filter 5d of FIG. 1) has a single output.

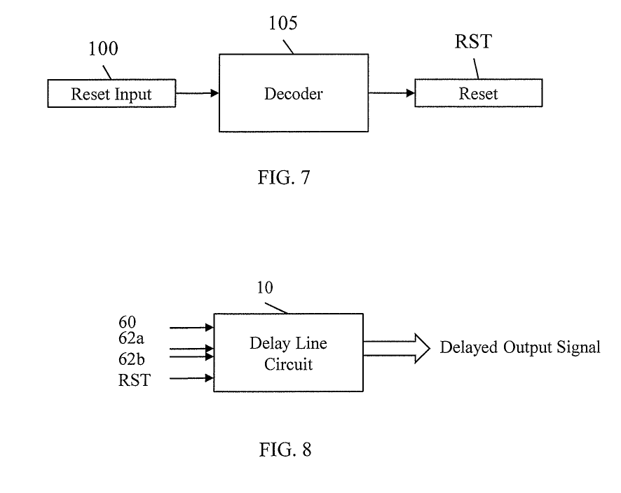

FIG. 7 shows a block diagram of a binary decoder. More specifically, FIG. 7 shows a reset input 100 provided to a decoder 105, which decodes the reset input 100 and outputs a reset signal RST, which can be provided to the delay cell(s), as shown in FIGS. 3-6. In embodiments, the decoder 105 can generate a reset signal RST for each operational state of the delay line circuit. More specifically, a delay line circuit having X delay cells has X unique reset inputs, i.e., a unique reset input for each of the delay cells. That is, an X bit reset vector is an input to the delay line circuit. In embodiments, the decoder 105 can be used to minimize an X bit vector to a Y bit vector where X<2^{Y}. In this way, each delay cell has a unique reset signal and can be operated using a binary coding scheme.

For example, a delay line circuit having six delay cells (i.e., X=6) has at least 2³ states (i.e., 8 states) and, as such, the decoder 105 can generate 8 different reset signals RST, as shown in Table 1. The decoder 105 can, for example, generate reset signal RST of “000000” to turn on all of the delay cells of a delay line circuit, and when a different operational state is necessary, e.g., a state requiring the last two delay cells disabled, the decoder 105 can generate a reset signal RST of 000011 to turn of the fifth and sixth delay cells and turn on the remaining delay cells. In this way, when the reset signal RST is high for a delay cell, the delay cell is turned off, and when the reset signal is low, the delay cell is turned on, as described with respect to FIGS. 3-6. In embodiments, cells of a delay line circuit are shut off, cell by cell, starting with the N^{th} cell (i.e., the final cell of the delay line circuit), followed by N−1^{th} cell, and so on, until the first cell is turned off. In embodiments, when a delay cell is turned off, clock propagation to succeeding cells in the delay line circuit is also cut off, even if the reset signals to the succeeding cells are enabled.

TABLE 1

| Input | Output = | |
|---|---|---|
| <1:3> | RST<1:8> | Cells |
| State 1 | 000000 | all cells on |
| State 2 | 000001 | cell 6 off |
| State 3 | 000011 | cells 5 and 6 off |
| State 4 | 000111 | cells 4-6 off |
| State 5 | 001111 | cells 3-6 off |
| State 6 | 011111 | cells 2-6 off |
| State 7 | 111111 | all cells off |
| State 8 | unused | unused |

FIG. 8 shows a block diagram of a delay line circuit 10. More specifically, FIG. 8 shows an input signal 60, for example, a clock or a strobe provided to the delay line circuit 10. In embodiments, one or more control voltages, e.g., control voltages 62a, 62b, are provided to the delay line circuit 10. FIG. 8 also shows a reset signal RST, as discussed with respect to FIG. 7, provided to the delay line circuit which generates a delayed output signal, e.g., output Z, Z1, Z2.

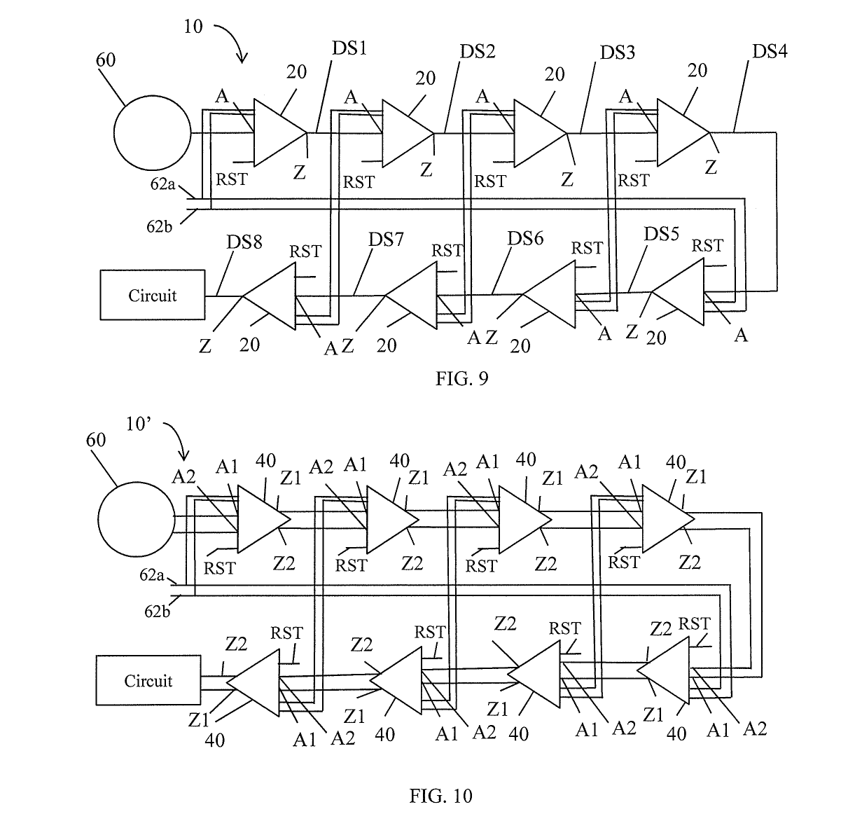

FIG. 9 shows a delay line circuit 10 having a single input and a single output. More specifically, FIG. 9 shows a delay line circuit 10 having eight delay cells 20 (e.g., delay cell 20 described with respect to FIG. 3) connected in series. It should be understood that FIG. 9 is only an exemplary embodiment, and that more or less delay cells 20 can also be implemented with the present invention. It should also be understood that the delay line circuit 10 as shown in FIG. 9 can be implemented using the delay cell 20′ shown in FIG. 4. Additionally, in embodiments, in a VCO 5e or delay elements 15e (of FIGS. 1 and 2) having X number of delay cells, each delay cell 20 generates a delay with a phase shift equivalent to 360/X degrees, and as such, the delay of each delay cell 20 used in delay line circuit 10 is equivalent to a phase shift of 360/X degrees.

In embodiments, an input signal 60, such as a clock or a strobe, is provided to an input A of the first delay cell 20. In embodiments, an output Z of each delay cell 20 is provided to an input A of a subsequent delay cell 20 in the delay line circuit 10. In embodiments, the output Z of the each delay cell 20 (i.e., the delayed output) in the delay line circuit 10 can be the output of the delay line circuit 10, such that each output, e.g., DS1-DS8, can be used for applications that require a delay input signal, e.g., input signal 60.

Still referring to FIG. 9, in embodiments, control voltages 62a, 62b are provided to each delay cell 20. In this way, the control voltages 62a, 62b are used to operate the first tail transistor 24 and second tail transistor 28 of the delay cell 20. In embodiments, the control signal used in the PLL 5 or DLL 15 (of FIGS. 1 and 2) are used as the control voltages 62a, 62b which operate the delay cells 20. More specifically, when the PLL 5 locks to a required frequency or DLL 15 locks to a required delay, corresponding control voltages 62a, 62b configure the delay cells 20 of the delay line circuit 10 as a function of that frequency.

In addition, FIG. 9 shows a reset signal RST connected to each delay cell 20. As such, each delay cell 20 receives the reset signal RST which turns on the delay cells 20 necessary for a particular operation. As a result, unnecessary delay cells 20 can be disabled, thus reducing power consumption of the delay line circuit 10. In embodiments, the VCO 5e of the PLL 5 (of FIG. 1) can be designed using one or more delay cells 20. In embodiments, the one or more delay cells 20 and the VCO 5e are not turned off, as this will result in a broken VCO ring and no VCO frequency signal. More specifically, the reset signal RST used in a VCO 5e is set to a low logic (i.e., RST=0). Similarly the delay elements 15e of the DLL 15 (of FIG. 2) can be designed using one or more delay cells 20. In embodiments, the delay cells are not turned off as this will result in a broken feedback connection to phase detector 15b due to no signal 15h.

FIG. 10 shows a delay line circuit 10′ having a dual input and a dual output. More specifically, FIG. 10 shows a delay line circuit 10′ having eight delay cells 40 (e.g., delay cell 40 described with respect to FIG. 5) connected in series. It should be understood that FIG. 10 is only an exemplary embodiment, and that more or less delay cells 40 can also be implemented with the present invention. It should also be understood that the delay line circuit 10′ as shown in FIG. 10 can be implemented using the delay cell 40′ shown in FIG. 6. A VCO 5e implemented with one or more delay cells 40 can be implemented with half the number of delay cells as a VCO ring implemented with one or more delay cells 20. More specifically, the dual outputs Z1, Z2 of 40 are complements of the inputs A1, A2, and as such, using complement outputs Z1, Z1 in the VCO ring requires half as many delay cells 40. Additionally, in a delay line circuit 10′ having X number of delay cells, each delay cell 40 generates a phase shift equivalent to 360/X degrees and its complement. Input signals 60′, such as a clock or a strobe, are provided to inputs A1, A2 of the first delay cell 40. In embodiments, outputs Z1, Z2 of each delay cell 40 are provided to inputs A1, A2 of the subsequent delay cell 40 in the delay line circuit 10′. In embodiments, the outputs of the each delay cell 40 (i.e., the phase output) in the delay line circuit 10′ can be the output of the delay line circuit 10′, such that each output can be used for applications that require a delayed input signal, as described herein.

Still referring to FIG. 10, in embodiments, control voltages 62a, 62b are provided to each delay cell 40. In this way, the control voltages 62a, 62b are used to operate the first tail transistor and second tail transistor of the delay cell 40. The control voltages 62a, 62b used in the delay line circuit 10′ correspond to control signals used to operate delay elements of the VCO 5e or DLL 15 (of FIGS. 1 and 2), as described herein. In addition, FIG. 10 shows a reset signal RST connected to each delay cell 40. In this way, each delay cell 40 receives the reset signal RST which turns on the delay cells 40 necessary for a particular operation. As a result, unnecessary delay cells 40 can be disabled, thus reducing power consumption of the delay line circuit 10′. In embodiments, the VCO 5e can be designed using one or more delay cells 40. In embodiments, the delay cells 40, and the VCO 5e are not turned off, as this will result in a broken VCO ring and no VCO frequency. More specifically, the reset signal RST used is a VCO 5e is set to a low logic (i.e., RST=0). Similarly, the delay elements 15e of the DLL 15 (of FIG. 2) can be designed using one or more delay cells 40. In embodiments, the one or more delay cells 40 are not turned off as this will result in a broken feedback connection to phase detector 15b due to no signal 15h.

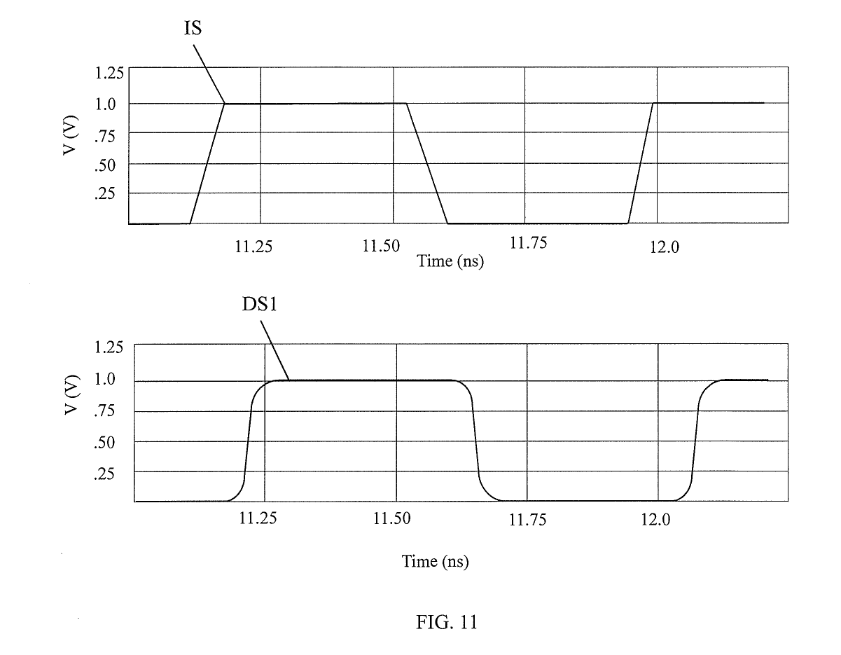

FIG. 11 shows a performance graph of a delay line circuit 10 in accordance with the present invention. More specifically, FIG. 11 shows a graph of a delay line circuit with the first delay cell turned on. The graph shows an input signal IS provided to the first delay cell and an output signal DS1 of the first delay cell 20. That is, the delay cell generates the delayed output DS1 based on the input signal IS. Subsequent delay cells in the delay line circuit are turned off, and their outputs DS2-8 (not shown) are set to a non-floating, pre-determined value, e.g., a logic low or a logic high.

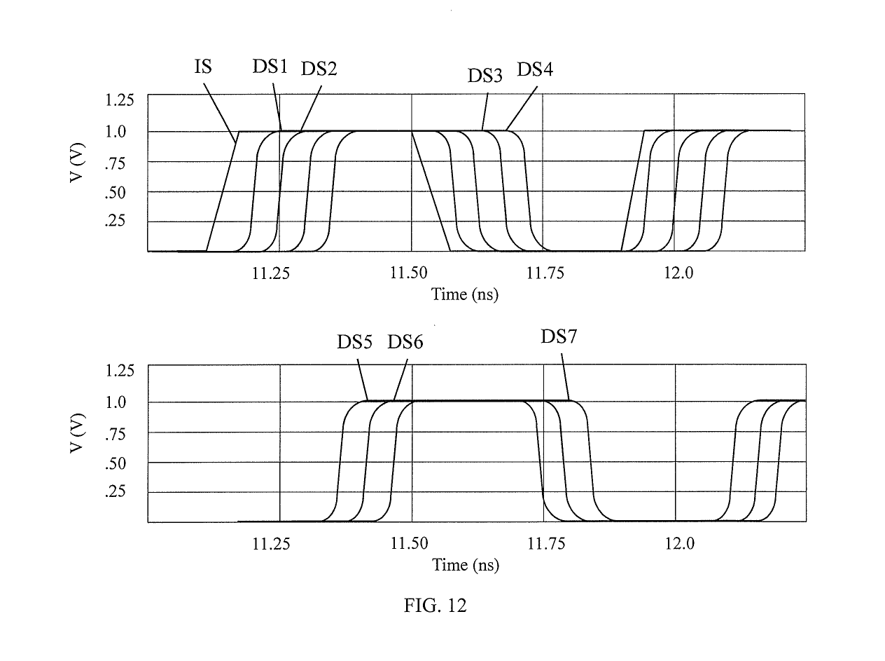

FIG. 12 shows a performance graph of a delay line circuit 10 in accordance with the present invention. More specifically, FIG. 12 shows a graph of a delay line circuit with the first seven delay cells turned on. The graph shows an input signal IS provided to a first delay cell of the delay line circuit and an output signal DS1 of the first delay cell provided as an input signal to a subsequent delay cell in the delay line circuit. That is, each delay cell generates a delay output signal based on the input signal received. As such, the delay line circuit generates seven output signals DS1-DS7, each subsequent output signal having a greater delay than its input signal. The eighth delay cell is turned off, and its output DS8 (not shown) is set to a non-floating, pre-determined value, e.g., a logic low or a logic high.

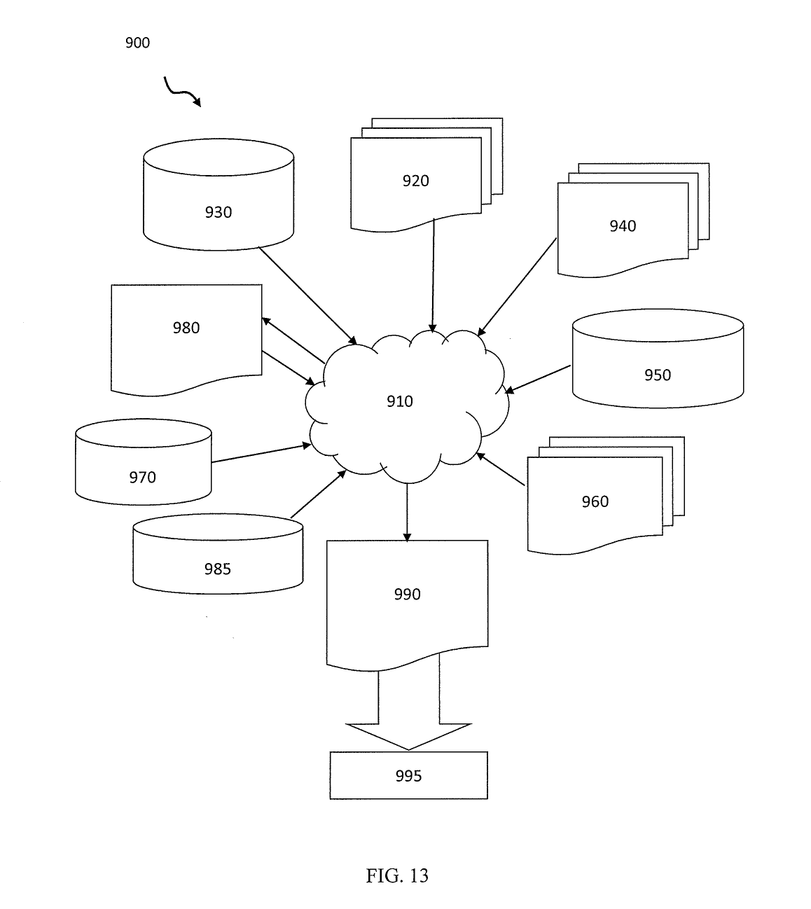

FIG. 13 is a flow diagram of an exemplary design flow 900 used for example, in semiconductor IC logic design, simulation, test, layout, and manufacture. Design flow 900 includes processes, machines and/or mechanisms for processing design structures or devices to generate logically or otherwise functionally equivalent representations of the design structures and/or devices described above and shown in FIGS. 3-6, 9 and 10. The design structures processed and/or generated by design flow 900 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 900 may vary depending on the type of representation being designed. For example, a design flow 900 for building an application specific IC (ASIC) may differ from a design flow 900 for designing a standard component or from a design flow 900 for instantiating the design into a programmable array, for example a programmable gate array (PGA) or a field programmable gate array (FPGA) offered by Altera® Inc. or Xilinx® Inc.

FIG. 13 illustrates multiple such design structures including an input design structure 920 that is preferably processed by a design process 910. Design structure 920 may be a logical simulation design structure generated and processed by design process 910 to produce a logically equivalent functional representation of a hardware device. Design structure 920 may also or alternatively comprise data and/or program instructions that when processed by design process 910, generate a functional representation of the physical structure of a hardware device. Whether representing functional and/or structural design features, design structure 920 may be generated using electronic computer-aided design (ECAD) such as implemented by a core developer/designer. When encoded on a machine-readable data transmission, gate array, or storage medium, design structure 920 may be accessed and processed by one or more hardware and/or software modules within design process 910 to simulate or otherwise functionally represent an electronic component, circuit, electronic or logic module, apparatus, device, or system such as those shown in FIGS. 3-6, 9 and 10. As such, design structure 920 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 910 preferably employs and incorporates hardware and/or software modules for synthesizing, translating, or otherwise processing a design/simulation functional equivalent of the components, circuits, devices, or logic structures shown in FIGS. 3-6, 9 and 10 to generate a netlist 980 which may contain design structures such as design structure 920. Netlist 980 may comprise, for example, compiled or otherwise processed data structures representing a list of wires, discrete components, logic gates, control circuits, I/O devices, models, etc. that describes the connections to other elements and circuits in an integrated circuit design. Netlist 980 may be synthesized using an iterative process in which netlist 980 is resynthesized one or more times depending on design specifications and parameters for the device. As with other design structure types described herein, netlist 980 may be recorded on a machine-readable data storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, buffer space, or electrically or optically conductive devices and materials on which data packets may be transmitted and intermediately stored via the Internet, or other networking suitable means.

Design process 910 may include hardware and software modules for processing a variety of input data structure types including netlist 980. Such data structure types may reside, for example, within library elements 930 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 940, characterization data 950, verification data 960, design rules 970, and test data files 985 which may include input test patterns, output test results, and other testing information. Design process 910 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 910 without deviating from the scope and spirit of the invention. Design process 910 may also include modules for performing standard circuit design processes such as timing analysis, verification, design rule checking, place and route operations, etc.

Design process 910 employs and incorporates logic and physical design tools such as HDL compilers and simulation model build tools to process design structure 920 together with some or all of the depicted supporting data structures along with any additional mechanical design or data (if applicable), to generate a second design structure 990. Design structure 990 resides on a storage medium or programmable gate array in a data foiinat used for the exchange of data of mechanical devices and structures (e.g. information stored in a IGES, DXF, Parasolid XT, JT, DRG, or any other suitable format for storing or rendering such mechanical design structures). Similar to design structure 920, design structure 990 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIGS. 3-6, 9 and 10. In one embodiment, design structure 990 may comprise a compiled, executable HDL simulation model that functionally simulates the devices shown in FIGS. 3-6, 9 and 10.

Design structure 990 may also employ a data format used for the exchange of layout data of integrated circuits and/or symbolic data format (e.g. information stored in a GDSII (GDS2), GL1, OASIS, map files, or any other suitable format for storing such design data structures). Design structure 990 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 3-6, 9 and 10. Design structure 990 may then proceed to a stage 995 where, for example, design structure 990: proceeds to tape-out, is released to manufacturing, is released to a mask house, is sent to another design house, is sent back to the customer, etc.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A delay cell using one or more analog control voltages, comprising:
a first gate transistor coupled to a voltage supply;
a second gate transistor coupled to ground; and
a reset signal provided to at least one of the first gate transistor and the second gate transistor, wherein the reset signal turns the delay cell on and off.

2. The delay cell of claim 1, wherein the reset signal is a binary code provided by a decoder.

3. The delay cell of claim 2, wherein the reset signal has a high logic which turns the delay cell off and the reset signal has a low logic which turns the delay cell on.

4. The delay cell of claim 1, further comprising at least one output signal set to a logic high or a logic low when a delay cell is turned off.

5. The delay cell of claim 1, further comprising:
a first tail transistor coupled to the first gate transistor;
a second tail transistor coupled to the second gate transistor; and
a body inverter coupled to at least the first tail transistor and the second tail transistor, the body inverter comprising a first inverter and a second inverter, the first inverter having a first pull-up transistor and a first pull-down transistor and the second inverter having a second pull-up transistor and a second pull-down transistor.

6. The delay cell of claim 5, wherein:
a source of the first tail transistor is coupled to a drain of the first gate transistor and a drain of the first tail transistor is coupled to the body inverter;
a source of the second tail transistor is coupled to a drain of the second gate transistor and a drain of the second tail transistor is coupled to the body inverter;
a gate of the first gate transistor is coupled to the reset signal;
a gate of the second gate transistor is coupled to an inverted reset signal; and
gates of the tail transistors are coupled to a respective one of the one or more analog control voltages.

7. The delay cell of claim 6, wherein:
a gate of the first pull-up transistor and a gate of the first pull-down transistor are coupled to an input signal;
a drain of the first pull-up transistor and a drain of the first pull-down transistor are coupled to a gate of the second pull-up transistor and a gate of the second pull-down transistor; and
a drain of the second pull-up transistor and a drain of the second pull-down transistor are coupled to an output signal.

8. The delay cell of claim 6, wherein:
a gate of the first pull-up transistor and a gate of the first pull-down transistor are coupled to a first input signal;
a drain of the first pull-up transistor and a drain of the first pull-down transistor are coupled to a first output signal;
a gate of the second pull-up transistor and a gate of the second pull-down transistor are coupled to a second input signal; and
a drain of the second pull-up transistor and a drain of the second pull-down transistor are coupled to a second output signal.

9. The delay cell of claim 5, wherein:
a source of the first tail transistor is coupled to the voltage supply;
a gate of the first tail transistor is coupled to a drain of the first gate transistor and to the reset signal by a first switch;
a drain of the first tail transistor is coupled to the body inverter;
a source of the second tail transistor is coupled to the ground;
a gate of the second gate transistor is coupled to a drain of the second gate transistor and to the reset signal by a second switch;
a drain of the second tail transistor is coupled to the body inverter;
a gate of the first gate transistor is coupled to an inverted reset signal; and
a gate of the second gate transistor is coupled to the reset signal.

10. The delay cell of claim 9, wherein the first and second switches are open when the reset signal has a high logic, and the first and second switches are closed when the reset signal has a low logic, such that the body inverter is decoupled from the voltage supply and the ground when the reset signal has a high logic.

11. The delay cell of claim 10, wherein:
a gate of the first pull-up transistor and a gate of the first pull-down transistor are coupled to an input signal;
a drain of the first pull-up transistor and a drain of the first pull-down transistor are coupled to a gate of the second pull-up transistor and a gate of the second pull-down transistor; and
a drain of the second pull-up transistor and a drain of the second pull-down transistor are coupled to an output signal.

12. The delay cell of claim 10, wherein:
a gate of the first pull-up transistor and a gate of the first pull-down transistor are coupled to a first input signal;
a drain of the first pull-up transistor and a drain of the first pull-down transistor are coupled to a first output signal;
a gate of the second pull-up transistor and a gate of the second pull-down transistor are coupled to a second input signal; and
a drain of the second pull-up transistor and a drain of the second pull-down transistor are coupled to a second output signal.

13. A delay line circuit, comprising:
a plurality of delay cells connected in series; and
a reset signal provided to the plurality of delay cells, wherein:
the reset signal turns the delay cells on and off individually;
the reset signal is a binary code provided by a decoder; and
the reset signal having a high logic turns the delay cell off and the reset signal having a low logic turns the delay cell on.

14. The delay line circuit of claim 13, wherein the delay cell comprises:
a first gate transistor coupled to a voltage supply;
a second gate transistor coupled to ground; and
a first tail transistor coupled to the first gate transistor;
a second tail transistor coupled to the second gate transistor; and
a body inverter coupled to at least the first tail transistor and the second tail transistor.

15. The delay line circuit of claim 14, further comprising:
at least one input signal provided to an input of a first delay cell of the plurality of delay cells;
one or more control voltages provided to each delay cell; and
at least one output signal, wherein:
at least one output of the delay cell is provided as at least one input to a next delay cell of the plurality of delay cells, and the at least one output of a last delay cell of the plurality of delay cells is the at least one output signal of the delay line circuit.

16. The delay line circuit of claim 15, wherein the at least one output is provided to a phase-locked loop or a delay-locked loop.

17. A method, comprising:
providing a reset signal to a plurality of delay cells of a delay line circuit; and
turning at least one of the plurality of delay cells off, cell by cell, based on the reset signal.

18. The method of claim 17, wherein a delay line circuit has N delay cells, which are shut off starting with the N^{th} cell, followed by N−1^{th} cell, and so on.

19. The method of claim 18, further comprising terminating an input signal propagation to delay cells succeeding a delay cell which is turned off.

20. The method of claim 19, wherein a delay line circuit having N cells requires 2^{N} operational states and a decoder generates a reset signal for each operational state.
